(19) United States
(12) Patent Application Publication
(10) Pub. No.: US 2012/0164379 A1
(43) Pub. Date: Jun. 28, 2012

(54) Wide Sheet Wafer

(75) Inventors: Steven Sherman, Newton, MA (US); Leo van Glabbeek, Franklin, MA (US); Weidong Huang, Bolton, MA (US); Stephen Yamartino, Wayland, MA (US); Kaitlin Olsen, Arlington, MA (US)

(73) Assignee: Evergreen Solar, Inc., Marlborough, MA (US)

(21) Appl. No.: 13/015,074

(22) Filed: Jan. 27, 2011

Related U.S. Application Data
(60) Provisional application No. 61/426,135, filed on Dec. 22, 2010.

(51) Int. Cl. B32B 3/00; C30B 15/20; B32B 5/00

(52) U.S. Cl. 428/141; 428/220; 428/172; 428/174; 117/13

(57) ABSTRACT

A sheet wafer has a generally flat, generally rectangular shaped body with a length and a width, and first and second filaments generally perpendicular to the width of the body. The first and second filaments are at least partially encapsulated by a wafer material and, together with the wafer material, form at least a portion of the body. The width is between about 145 mm and 165 mm.

### PRIORITY

This patent application claims priority from provisional U.S. patent application No. 61/426,135, filed Dec. 22, 2010, entitled, “WIDE SHEET WAFER,” and naming Steven Sherman, Leo Van Glabbeek, Weidong Huang, Stephen Yamartino, and Kaitlin Olsen as inventors, the disclosure of which is incorporated herein, in its entirety, by reference.

### RELATED APPLICATIONS

This patent application is related to co-pending U.S. patent application Ser. No. ______, filed on even date herewith, entitled, “CONTROLLING THE TEMPERATURE PROFILE IN A SHEET WAFER,” and naming Kaitlin Olsen, Weidong Huang, and Christine Richardson as inventors, the disclosure of which is incorporated herein, in its entirety, by reference.

### FIELD OF THE INVENTION

The invention generally relates to sheet wafers and, more particularly, the invention relates to growing wide sheet wafers.

### BACKGROUND ART

Silicon wafers are the building blocks of a wide variety of semiconductor devices, such as solar cells, integrated circuits, and MEMS devices. For example, Evergreen Solar, Inc. of Marlboro, Mass. forms solar cells from silicon sheet wafers fabricated by passing two filaments through a crucible of silicon melt. This type of wafer may be referred to as “filament sheet wafers,” and are known in the industry as STRING RIBBON™ wafers.

Filament sheet wafers in use today typically have widths of about 81 mm. While useful and widely distributed across the world, sheet wafers having this width are not in line with the currently industry standard size of about 156 mm for solar cells. Wafers known to the inventors having 156 mm widths use a different technology. For example, one such different type of wafer is known as a “cast wafer.” Making filament sheet wafers as wide as cast wafers presents a number of unique, complicated challenges.

### SUMMARY OF THE INVENTION

In accordance with one embodiment of the invention, a sheet wafer has a generally flat, generally rectangular shaped body with a length and a width, and first and second filaments generally perpendicular to the width of the body. The first and second filaments are at least partially encapsulated by a wafer material and, together with the wafer material, form at least a portion of the body. The width is between about 145 mm and 165 mm.

For example, the width may be between about 155 mm and 157 mm (e.g., 156 mm). The wafer material may include any of a number of different materials, such as multi-crystalline silicon, polycrystalline silicon, or single crystal silicon. To improve electrical efficiency, in some embodiments, a plurality of grains within the body (e.g., within a filament sheet wafer) have a minimum dimension of about 2 centimeters. These grains preferably make up a majority of the surface area of the top or bottom surface of the grown wafer.

The width of the body may be defined by two sides that are generally parallel with the first and second filaments. Each side is defined at least in part by the wafer material. The wafer may have an irregular thickness between the filaments. Despite that, the wafer may have an average thickness between about 80 and 170 microns.

Various embodiments control the inherent stress in the growing wafer to mitigate wafer bow. Thus, the generally flat body may have a bow of no greater than about 2.5 millimeters. For example, the generally flat body may have a bow of less than about 2 millimeters. Moreover, the body may have a smooth top (or bottom) face. For example, the top face may have a surface roughness RMS value of between about 0.005 microns and about 0.04 microns.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a sheet wafer configured in accordance of illustrative embodiments of the invention.

FIG. 2 schematically shows a perspective view of a portion of a sheet wafer growth system according to illustrative embodiments of the present invention.

FIG. 3 schematically shows a partially cut away view of the sheet wafer growth system of FIG. 2 with part of the housing removed.

FIG. 4 schematically shows a cross-sectional view of a sheet wafer growth system having a shield adjacent to both an afterheater and to base insulation according to various embodiments of the present invention.

FIG. 5 schematically shows a cross-sectional view of a sheet wafer growth system having a shield adjacent to an afterheater according to various embodiments of the present invention.

FIG. 6 schematically shows a partially cut away view of a sheet wafer growth system having a shield adjacent to an afterheater and coupled to a housing according to various embodiments of the present invention.

FIGS. 7A and 7B schematically show cross-sectional views of a portion of a sheet wafer growth system having a shield coupled to base insulation according to some embodiments of the present invention.

FIG. 8A schematically shows a perspective view of one portion of an afterheater with a plurality of sheets according to various embodiments of the present invention.

FIG. 8B schematically shows a cross-sectional view of one portion of the afterheater shown in FIG. 8A.

FIGS. 9A-9C schematically show various plate or rib configurations with different densities according to illustrative embodiments of the present invention.

FIG. 10 schematically shows a sheet or rib configuration having two or more densities within the material according to illustrative embodiments of the present invention.

FIGS. 11A-11C schematically show perspective views of one portion of an afterheater with a shield having various sheet and rib widths according to various embodiments of the present invention.

FIG. 12A-12D schematically show perspective views of various plate configurations according to some embodiments of the present invention.

FIG. 13 schematically shows a different view of a wafer fabrication furnace configured in accordance with illustrative embodiments of the invention.

FIG. 14 shows a process of forming a sheet wafer in accordance with illustrative embodiments of the invention.

FIG. 15 schematically shows a photovoltaic panel using wafers configured in accordance with illustrative embodiments of the invention.

FIG. 16 schematically shows a top view of a photovoltaic cell configured in accordance with illustrative embodiments of the invention.

### DESCRIPTION OF ILLUSTRATIVE EMBODIMENTS

In illustrative embodiments, a sheet wafer, such as a filament sheet wafer, has a width of greater than about 145 mm. For example, the sheet wafer can have a width of between about 155 and 157 mm, such as about 156 mm—the current industry standard width for wafers used in photovoltaic cells (a/k/a “PV cells”). Details of illustrative embodiments are discussed below.

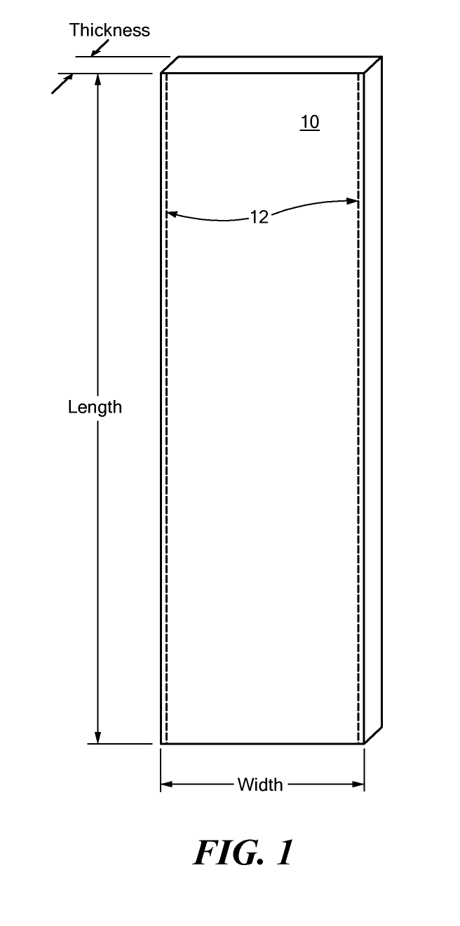

FIG. 1 schematically shows a filament sheet wafer 10 configured in accordance illustrative embodiments of the invention. For example, the wafer 10 may be similar to STRING RIBBON wafers, distributed by Evergreen Solar, Inc. of Marlboro, Mass. In a manner similar to other filament sheet wafers, this sheet wafer 10 has a generally rectangular shape and a relatively large surface area on its front and back faces.

The thickness of the sheet wafer 10 varies and is very thin relative to its length and width dimensions (discussed below). Despite this range, the filament sheet wafer 10 may be considered to have an average thickness across its length and/or width. For example, the sheet wafer 10 may have a thickness ranging from about 80 microns to about 320 microns across its width. Some embodiments have an average thickness of between 100 and 200 microns, such as about 170 microns. The filament sheet wafer 10 may primarily include any of a wide variety of crystal types, such as multi-crystalline, single crystalline, polycrystalline, microcrystalline or semi-crystalline material (e.g., silicon).

As known by those skilled in the art, the filament sheet wafer 10 is formed from a pair of filaments 12 (also referred to as “strings,”) substantially encapsulated by silicon (e.g., multi-crystalline or single crystal silicon). The silicon may extend slightly outwardly of the filament 12 to generally form the edge of the sheet wafer 10. FIG. 1 illustrates this by showing the filament 12 as dashed lines-in phantom—traversing along the length of the wafer 10. The silicon may have small grains, or a plurality of large grains. For example, the large grains could have minimum outer dimensions that are equal to or exceed about two centimeters. In alternative embodiments, one or more of the filaments 12 may be generally coincident with the edge of the sheet wafer 10.

For purposes of this discussion, the distance between the edges (of the wafer 10) that are parallel with the filaments 12 is considered to be the “width” of the wafer 10. FIG. 1 explicitly highlights this dimension. The filaments 12 thus are considered to extend generally perpendicular to the width of the body. The two edges (or sides) forming the width thus may be considered, from the perspective of FIG. 1, “left and right edges or sides.” In a corresponding manner, FIG. 1 also explicitly shows the “length” dimension, which is generally perpendicular to the width—generally parallel with the filaments 12. Again, from the perspective of FIG. 1, the two edges or sides forming the length can be considered “top and bottom sides/edges.”

The length of the wafer 10 can vary significantly depending upon where automated processes and/or operators cut the sheet wafer 10 as it is growing. Automated processes and/or operators preferably cut/separate the sheet wafer 10 in a manner that produces smaller wafers 10 of generally uniform length. In various embodiments, due to the wafer cutting process (discussed below), the top and bottom edges of the wafer 10 expose the terminal ends or tips of the filaments 12.

In accordance with illustrative embodiments of the invention, the wafer 10 has a width that is larger than those in conventional filament sheet wafers known to the inventors. For example, the width of the wafer 10 may exceed about 140 millimeters. In some embodiments, the wafer 10 has a width of between 145-165 millimeters, or about 156 millimeters.

The body of illustrative embodiments of the sheet wafer 10 thus may have any of the following approximate widths:

Width
145 mm
146 mm
147 mm
148 mm
149 mm
150 mm
151 mm
152 mm
153 mm
154 mm
155 mm
156 mm
157 mm
158 mm
159 mm
160 mm
161 mm
162 mm
163 mm
164 mm
165 mm

Of course, illustrative sheet wafers 10 can have widths that are between these noted dimensions. For example, the wafer 10 can have a width of about 164.75 mm. In fact, illustrative embodiments can apply to wafers 10 having smaller widths, or larger widths, although larger widths present similar challenges to those discussed immediately below.

More specifically, wafers 10 having these wide widths present a number of problems and complex thermodynamic design challenges that are much less of an issue with filament sheet wafers 10 having narrower widths. Specifically, during the wafer growth process, stresses created during the wafer cooling/solidifying process can create undesired curvature or bowing in the wafer 10. Bowing may be considered a form of wafer warping. The likelihood of excessive stresses, and therefore bowing, is greatly enhanced as the wafers 10 become wider.

If the amount of bowing (i.e., the “bow”) is too large, then the wafer 10 generally has little commercial value as it will be more prone to breakage during and after fabrication. For example, when used in a solar cell, processes typically screen print silver or some other metal on the front and back faces of the filament sheet wafer 10 (discussed in greater detail below). Many conventional screen print processes require substantially flat wafers 10—otherwise, the screen printing process may shatter the very thin and fragile wafer 10. This can significantly reduce yield, thus increasing costs.

To understand bow, one may consider an ideal filament sheet wafer 10, which is perfectly planar. As discussed above, however, filament sheet wafers 10 often have a varying thickness across their bodies. An ideal, variable-thickness filament sheet wafer 10 thus has its entire body below the thickest parts of the thickness. The thickest parts of the thickness may be considered to form an “ideal plane.” In practice, however, regardless of the wafer width, there may be some portions of the body that undesirably bend to cause some edge or side to extend out of the ideal plane.

In illustrative embodiments, the filament sheet wafer 10 has no edge, face, or other portion that extends more than a pre-selected amount out of plane of the ideal plane. For example, the wafer 10 may not extend out of plane of the ideal plane by more than about 2.5 millimeters. Thus, wafer fabrication and quality control processes reject wafers having any part that extends more than about 2.5 millimeters out of the ideal plane. For example, a wafer 10 having an edge that extends about 2.8 millimeters out of plane may be considered as having “a bow of 2.8 millimeters.”

One simple way of determining if the bow is less than the maximum permissible amount is to position the wafer 10 on a generally flat conveyer belt, and pass the wafer 10 underneath a bar or member that is about 2.5 millimeters or less above the ideal plane (i.e., about 2.5 millimeters above the highest portion of the top face). For example, some processes conduct this test at about 2.0 millimeters above the ideal plane. If the wafer 10 passes underneath the bar or member, it has acceptable bow and can be used commercially in solar cells. If it does not pass underneath the bar, then it is rejected as having too much bow. It is expected that the edges (and not the faces) of rejected wafers 10 may be most out of plane. There may be interior portions on the face of the wafer 10, however, that are out of plane and can be the cause for the wafer rejection.

Narrower filament sheet wafers, such as those distributed by Evergreen Solar, Inc., typically minimize the bowing problem since they can withstand stress without, on average, excessively bowing. This is not the case for wider wafers 10. More particularly, wider wafers 10 have the undesired effect of amplifying stress, due to their longer widths, causing greater bow. For example, a bend or warped portion located near the center of the wafer 10 causes the edge of a wide wafer 10 to be much higher (more out of plane) than that of a narrow wafer. In fact, these warped portions undesirably can cause out of plane changes along the length of the wafer 10 as well as to the width. In fact, the wafer 10 can have two or more warped portions that impact an edge even further, and this is more likely to happen with wafers 10 having more area (e.g., wider wafers 10).

Bowing thus is a significant problem. To control stresses that cause bow, the inventors realized that the temperature profile of the growing wafer 10 must be carefully controlled. After successive experiments, the inventors discovered that they could control the temperature profile, and successfully grow commercial grade filament sheet wafers 10 with acceptable bow tolerances.

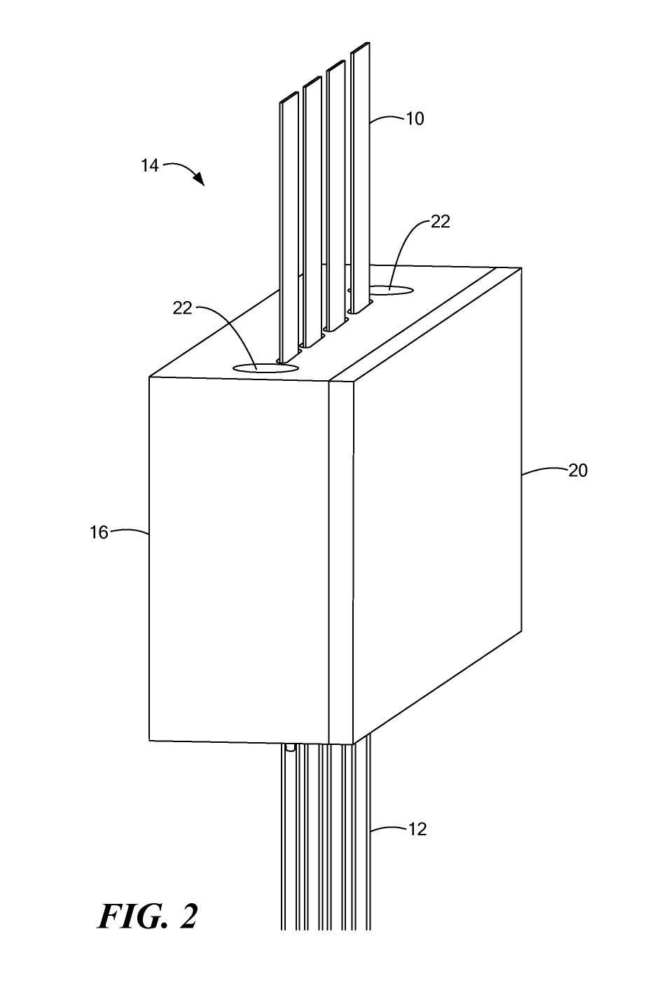

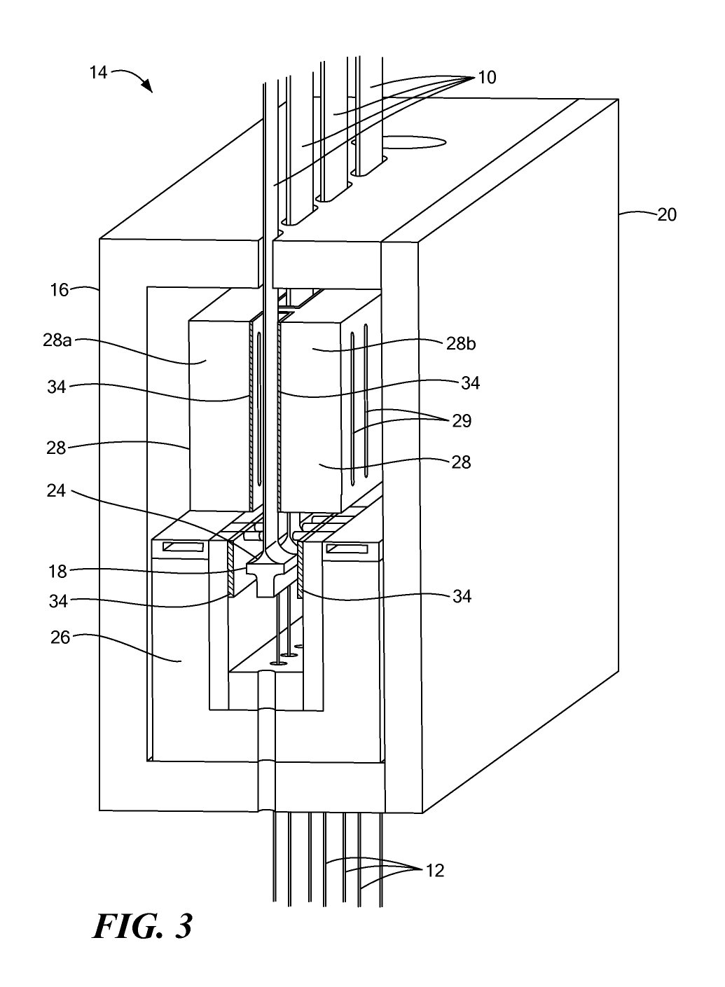

Specifically, as known by those in the art, filament sheet wafers 10 are grown in high temperature filament sheet wafer growth furnaces. FIG. 2 schematically shows a sheet wafer furnace 14 according to various embodiments of the present invention. The furnace 14 may include a housing 16 forming an enclosed or sealed interior (shown in subsequent figures). The interior may be substantially free of oxygen (e.g., to prevent combustion) and include one or more gases, such as argon or other inert gas, that may be provided from an external gas source. The interior includes a resistively heated crucible 18 (as shown in FIGS. 3-7B) for containing molten silicon, and other components for substantially simultaneously growing one or more silicon sheet wafers 10. Although FIG. 2 shows four sheet wafers, the furnace 14 may substantially simultaneously grow fewer or more of the filament sheet wafers 10. For example, the furnace 14 may grow two wide sheet wafers 10 (also referred to as “crystal sheets 10”).

The housing 16 may include a door 20 to allow access to and inspection of the interior and its components, and one or more optional viewing windows 22. The housing 16 also has an inlet (not shown) for directing feedstock material, such as silicon pellets, into the interior of the housing 16 to the crucible 18. It should be noted that discussion of the silicon feedstock and silicon sheet wafers 10 is illustrative and not intended to limit all embodiments of the invention. For example, the sheet wafers 10 may be formed from other materials, e.g., metals or alloys.

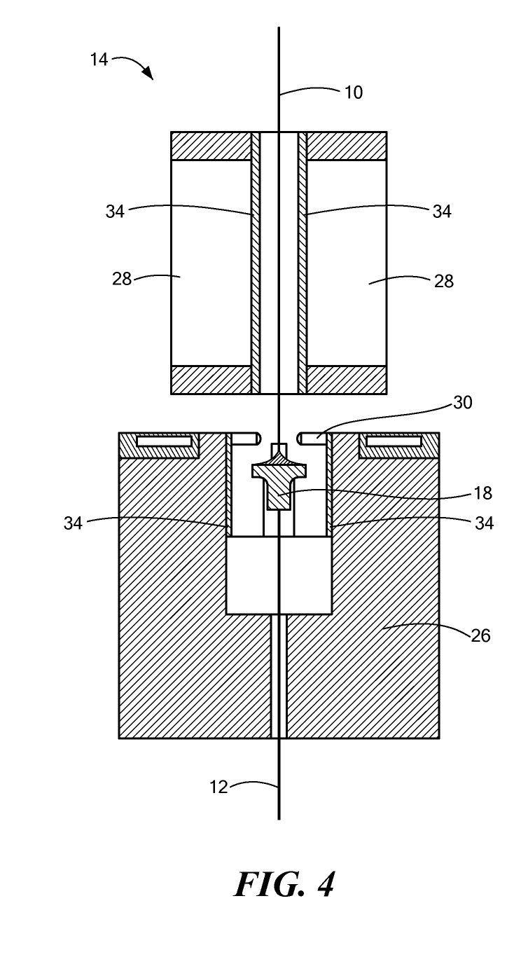

FIG. 3 schematically shows a partially cut away view of a furnace 14 with part of the housing 16 removed, while FIG. 4 schematically shows a cross-sectional view of a growth system with the housing 16 removed. As noted above, the furnace 14 includes the crucible 18 for containing molten material 24 in the interior of the housing 16. In one embodiment, the crucible 18 may have a substantially flat top surface that may support or contain the molten material 24. The crucible 18 may include filament holes (not shown) that allow one or more filaments 12 to pass through the crucible 18. As the filaments 12 pass through the crucible 18, portions of the molten silicon solidify at respective surface menisci, thus forming the growing sheet wafer 10 between each respective pair of filaments 12. To facilitate the side-by-side wafer growth, the crucible 18 has an elongated shape with a region for growing sheet wafers 10 in the side-by-side arrangement along its length. Alternative embodiments, however, may grow the wafers in a face to face manner.

To at least in part control the temperature profile in its interior, the furnace 14 has insulation that is formed based upon the thermal requirements of the regions in the housing 16. For example, the insulation is formed based on 1) the region containing the molten material 24 (i.e., the crucible 18), and 2) the region containing the resulting growing sheet wafer 10 (the afterheater 28, discussed immediately below). To that end, the insulation includes a base insulation 26 that forms an area containing the crucible 18 and the molten material 24, and an afterheater 28 positioned above the base insulation 26 (from the perspective of the drawings).

The afterheater 28 is important to the bowing issue—it is where the just formed wafer 10 cools from very high temperatures toward ambient temperatures. Ideally, the afterheater 28 causes the rate of change of cooling in both the X and Y directions across the wafer to be substantially constant. More specifically, those in the art are familiar with the Laplace Equation below:

$$\frac{{\partial }^{2} T}{\partial {x}^{2}} + \frac{{\partial }^{2} T}{\partial {y}^{2}} = 0$$

The inventors have configured the afterheater toward that end. Specifically, the afterheater 28 may be supported by the base insulation 26, e.g., by posts (not shown) and have specially configured insulation of its own to control the temperature profile of the cooling wafer. In some embodiments, the afterheater 28 has two portions (28a, 28b) that are positioned on either side of the growing sheet wafers 10. The two portions 28a, 28b form one or more channels through which the wafers grow. Alternatively, the afterheater 28 may also be positioned on only one side of the growing sheet wafers 10. In some embodiments, the afterheater 28 has one or more additional openings or slots 29 for controllably venting heat from the growing sheet wafers 10 as it passes through the inner surface of the afterheater 28.

In some embodiments, the furnace 14 also may include a gas cooling system that supplies gas from an external gas source (not shown), through a gas cooling manifold, to gas jets 30. The gas cooling system may provide gas to further cool the growing sheet wafer 10 and control its thickness. For example, as shown in FIGS. 3-7B, the gas cooling jets 30 may face toward the growing sheet wafer 10 in the area above the crucible 18—toward the above noted meniscus extending from the melt and containing the wafer 10.

In illustrative embodiments, the furnace 14 also has one or more shields 34 that each have two or more regions with substantially different thermal conductivities. These different thermal conductivities control the temperature profile in the growing sheet wafers 10. Various configurations of the shields 34 are discussed in more detail below. More generally, as noted above, during the growth and cooling process, the growing wafers 10 often have internal stresses caused by temperature variations that cause various areas of the wafers 10 to cool faster or slower than other areas. In addition, stresses may develop between the sheet wafer 10 and the filaments 12 due to the differences between the coefficient of thermal expansion of these two materials. Accordingly, to control the temperature profile with each sheet wafer as it cools, the shield 34 is configured to cool the different portions of the wafers in a manner that minimizes stress—i.e., in an effort to satisfy the Laplace Equation above.

The inventors used empirical methods to determine how best to configure the shield 34. To that end, among other things, the inventors determined the temperature profile within the furnace afterheater 28, focusing on the areas that have varying rates of cooling. Based on this information, the inventors iteratively formed an effective shield design (discussed in greater detail below) that can mitigate bow to produce commercial grade sheet wafers (e.g., wafers 10 with bow of less than about 2.5 millimeters).

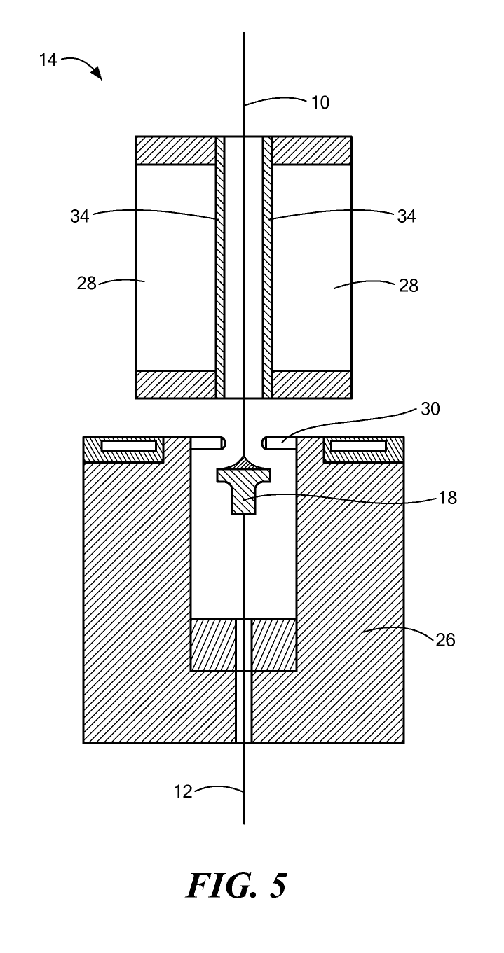

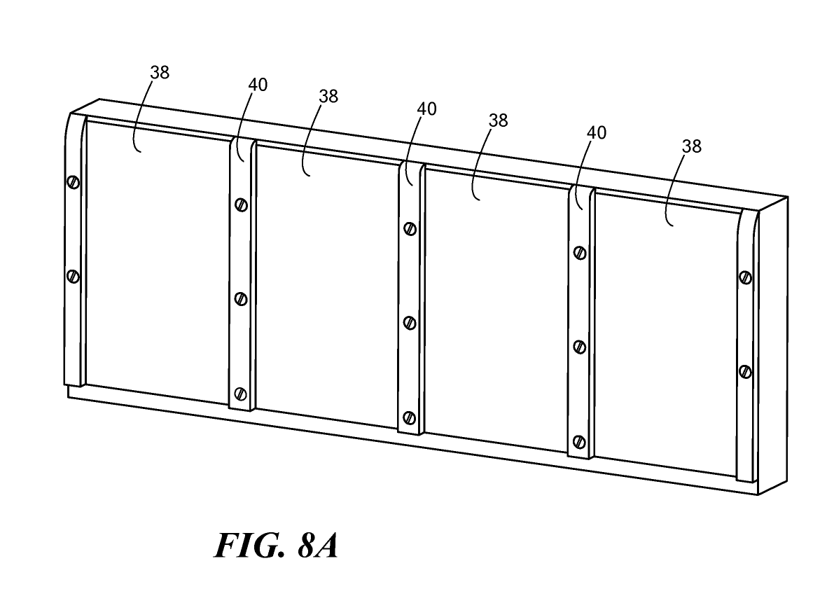

The shield 34 may be adjacent to at least a portion of the afterheater 28, positioned between the afterheater 28 and the sheet wafers 10. Preferably, the shield 34 is adjacent to the afterheater 28 on either side of the sheet wafers 10. The shield 34 may be coupled to the inner surface of the afterheater 28, as shown in FIG. 5, or may be attached to the top of the afterheater 28 (not shown). Although FIG. 5 shows the shield 34 on the inner surface of the afterheater 28, the shield 34 may also be included on other surfaces of the afterheater 28, such as discussed below with respect to FIG. 8B.

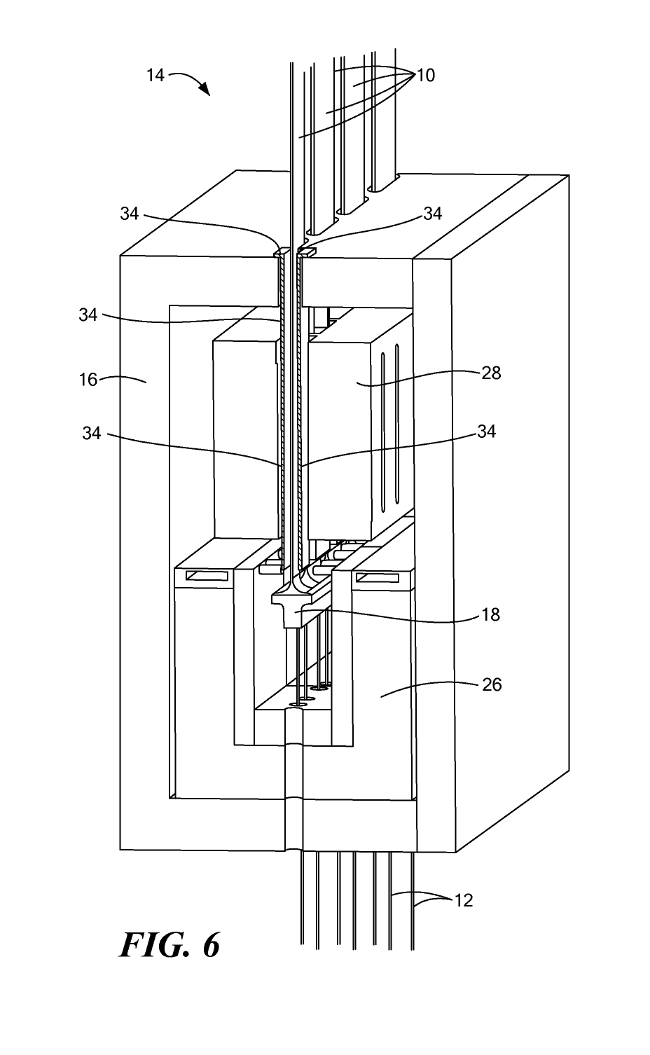

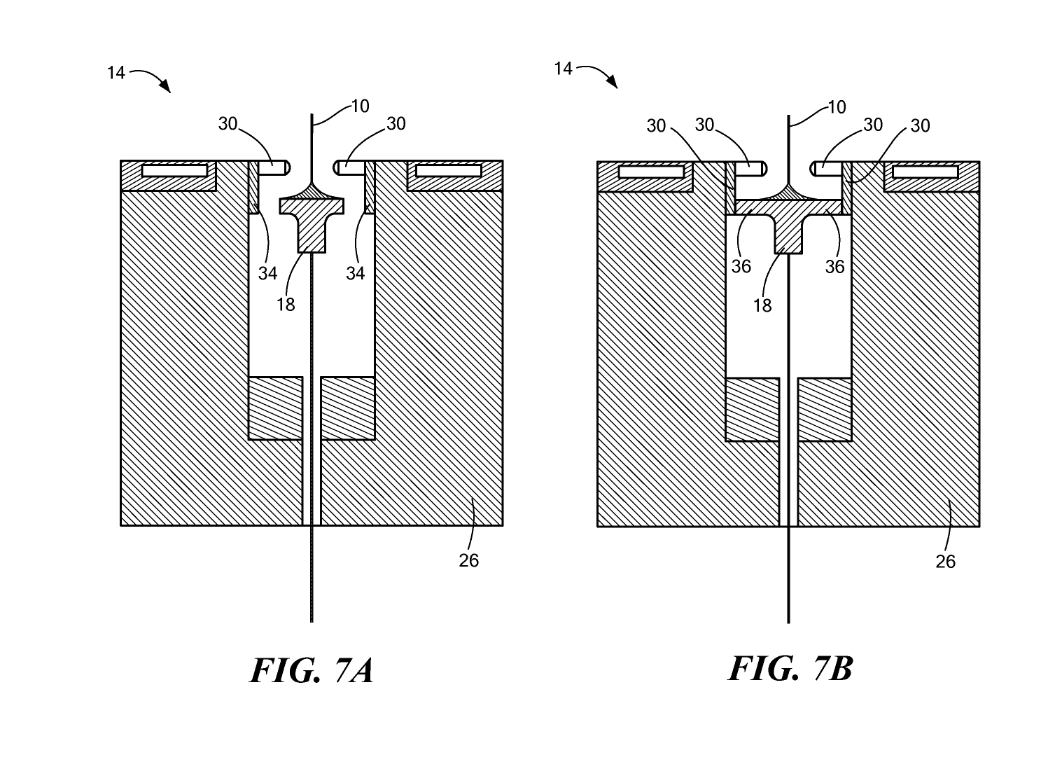

Alternatively, as shown in FIG. 6, the shield 34 may be attached to the top of the housing 16 and positioned adjacent to the channel in the housing 16. In this embodiment, the shield 34 may extend downwardly, ending somewhere above the crucible 18. Alternatively, or in addition, the shield 34 may be coupled to at least a portion of the base insulation 26 positioned between the base insulation 26 and the crucible 18. For example, FIGS. 7A and 7B schematically show a cross-sectional view of a bottom portion of a sheet wafer furnace 14 having a shield 34 coupled to the base insulation 26. Preferably, the shield 34 is coupled to the base insulation 26 on either side of the crucible 18 and ends somewhere below the top of the crucible 18. The shields 34 and the crucible 18 may have a space between them, such as shown in FIG. 7A.

Alternatively, the upper section of the crucible 18 may include one or more baffles 36 that extend to the shields 34 on either side of the crucible 18 to adjoin one another. The baffles 36 may prevent contaminants from the base insulation 26 from being incorporated into the growing sheet wafer 10 near the molten material 24. In any of these examples, the temperature profile in the sheet wafer 10 illustratively is controlled during the majority of the cooling process.

The shield 34 also may be positioned in other locations. For example, the top of the shield 34 may extend above the top of the base insulation 26, not shown, may extend somewhere between the base insulation 26 and the afterheater 28, or may adjoin the bottom of the afterheater 28.

The inventors expect that the shield 34 may become contaminated during the wafer growth process. For example, molten silicon may splash on its face, Accordingly, whether it is adjacent to the afterheater 28, adjacent to the base insulation 26, or both, the shield 34 preferably is removably coupled to the afterheater 28, the housing 16, and/or the base insulation 26. Thus, if contaminated, a technician or automated process may remove the shield 34 for cleaning, or for a complete replacement. Conventional securing techniques (e.g., with heat resistant screws) may provide this connection. Moreover, one or more shields 34 may be used for each sheet wafer 10 grown in the furnace 14, or one or more shields 34 may be used for all of the sheet wafers 10 grown in the growth system.

The inventors believe that gas can carry contaminants from the insulation materials surrounding the growing wafer 10 to the wafer surface as the wafer 10 cools in the afterheater 28. Thus, in addition to controlling the temperature profile in the afterheater 28, the shield 34 also forms a protective barrier in the system to reduce gas borne contaminants undesirably emitted from the base insulation 26 and/or the afterheater 28.

To that end, portions of the shield 34 preferably are formed from a very pure, high quality material that are able to withstand relatively high temperatures. For example, the shield material is expected to operate in temperatures ranging from about 1000 degrees C. to about 1500 degrees C. One satisfactory material for forming the base insulation 26 and/or the afterheater 28 thus may include a low density carbon insulation material, such as carbon foam, carbon fiber, or graphite foam material. Thus, portions of the shield 34 may be formed from a variety of materials that have a higher purity than those and typical insulation materials.

Other portions of the shield 34, however, may be formed from the same or similar materials as the base insulation 26 and/or the afterheater 28. Preferably, one or more portions of the shield 34 are formed from a hard, dense material. For example, portions of the shield 34 may be formed of silicon carbide, quartz, graphite, aluminum oxide or a combination thereof. The shield 34 may be a layer, such as a cladding layer, formed on or coupled to the base insulation 26 and/or the afterheater 28. Alternatively, the shield 34 may be a coating formed on the base insulation 26 and/or the afterheater 28 or formed on a shield material, e.g., CVD silicon carbide coating graphite.

In some embodiments, the shield 34 is formed from a plurality of plates 38 attached to the base insulation 26 and/or the afterheater 28 with one or more ribs 40. For example, FIGS. 8A and 8B schematically show a perspective view and cross-sectional view, respectively, of a shield 34 with a plurality of plates 38 coupled to the inner surface of an afterheater 28 with one or more ribs 40. In addition to the inner surface of the afterheater 28 and/or the base insulation 26, the shield 34 may also be secured to other surfaces of the afterheater 28 or base insulation 26. For example, the shield 34 may substantially surround the afterheater 28, such as shown in FIG. 8B.

Consistent with its principal function, the plates 38 and the ribs 40 of FIG. 8A preferably are positioned in the afterheater 28 and/or the base insulation 26 in a manner that controls the temperature gradients near the growing/cooling sheet wafer 10, reducing sheet stresses. For example, as the filaments 12 pass through the crucible 18, molten silicon solidifies at the surface, thus forming a growing sheet wafer 10 between the two filaments 12. Undesirably, there may be portions of the growing sheet wafer 10 that, absent some further cooling, may be thinner than intended (e.g., forming thin, fragile “neck regions”). Therefore, the ribs 40 may be positioned near those sections of the growing sheet wafer 10 to act as heat sinks, ensuring appropriate cooling and thus, the desired thickness in the sheet wafer 10.

Accordingly, the plates 38 and ribs 40 may be formed from a material that has substantially different thermal conductive properties from one another. For example, the ribs 40 may be formed from a material that has a higher heat conductive property than that of the plates 38. For instance, the plates 38 may be formed of silicon carbide, quartz, aluminum oxide and/or a low density, carbon fiber insulation material, such as FIBERFORM, and the ribs 40 may be formed of graphite and/or aluminum oxide.

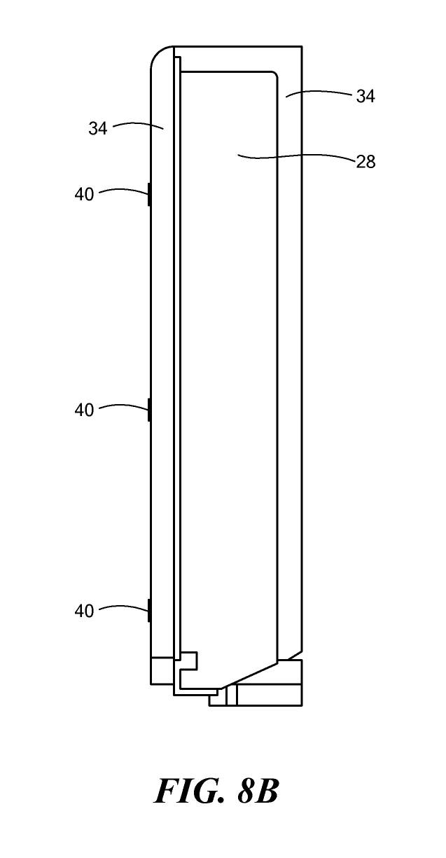

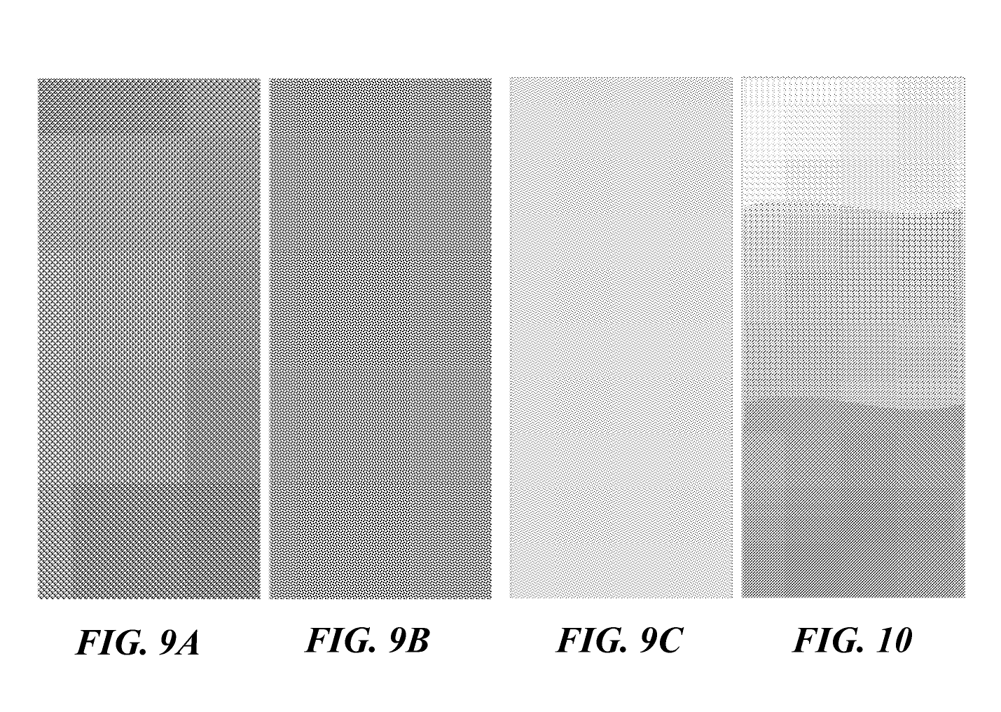

Alternatively, or in addition, the plates 38 and ribs 40 may be formed from substantially the same type of material, but the density of the material may be different so that each has effectively different thermal conductive properties from one another. For example, FIGS. 9A-9C show plates 38 and/or ribs 40 with different densities from one another. Alternatively, or in addition, the plates 38 and/or ribs 40 may have two or more densities within the same material, such as shown FIG. 10. This allows the configuration of the plates 38 and/or ribs 40 to vary both in the horizontal direction, e.g., from side-to-side in the growing sheet wafer 10, and/or in the vertical direction, e.g., from top-to-bottom in the growing sheet wafer 10 from the perspective of the drawings.

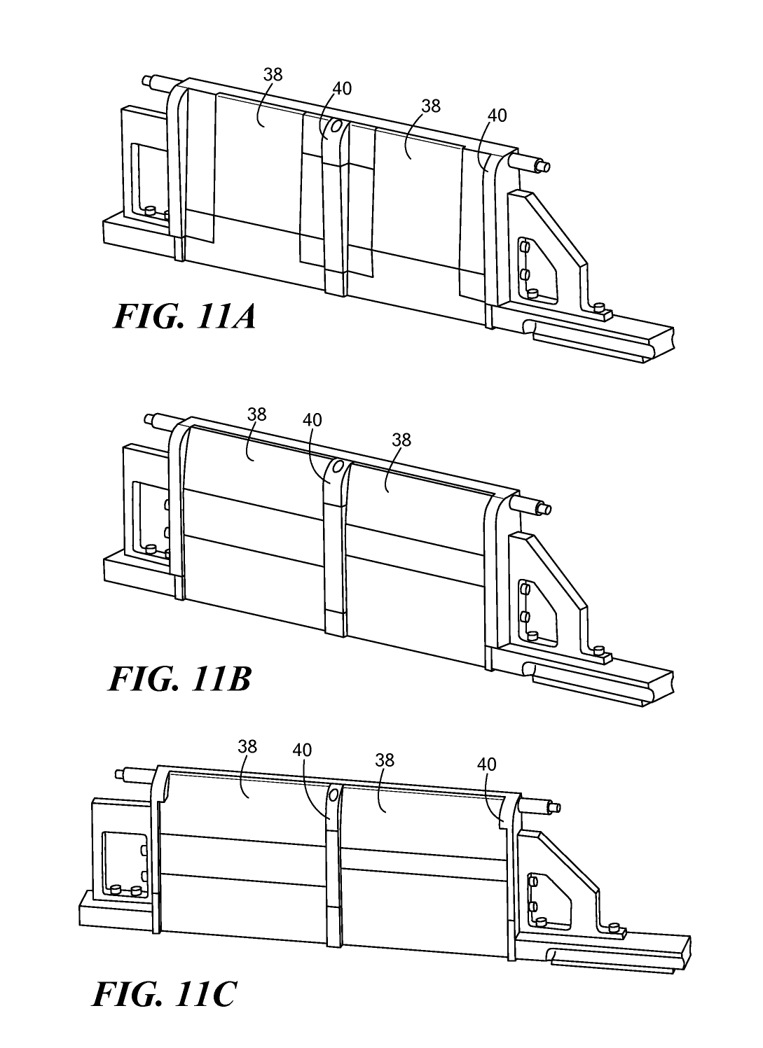

The configuration of the plates 38 and ribs 40 may be varied depending on the desired characteristics and qualities of the growing sheet wafers 10. For example, as shown in FIG. 11A, the outer portions of the plates 38 adjacent to the ribs 40 may be formed from materials having similar thermal conductive properties as the ribs 40, effectively enlarging the cooling areas in the sheet wafer 10. Alternatively, or in addition, a larger or smaller rib 40 may be used at the sides of the plates 38 to effectively enlarge or reduce the cooling areas in the sheet wafer 10, such as shown in FIGS. 11B and 11C. The size and shape of the plates 38 and/or the ribs 40 may be readily changed to allow various cooling designs to be evaluated during development. Also, the plate 38 and rib 40 configuration may be readily be changed to compensate for process variations, such as a material variation within the insulation material, to achieve a consistent cooling profile.

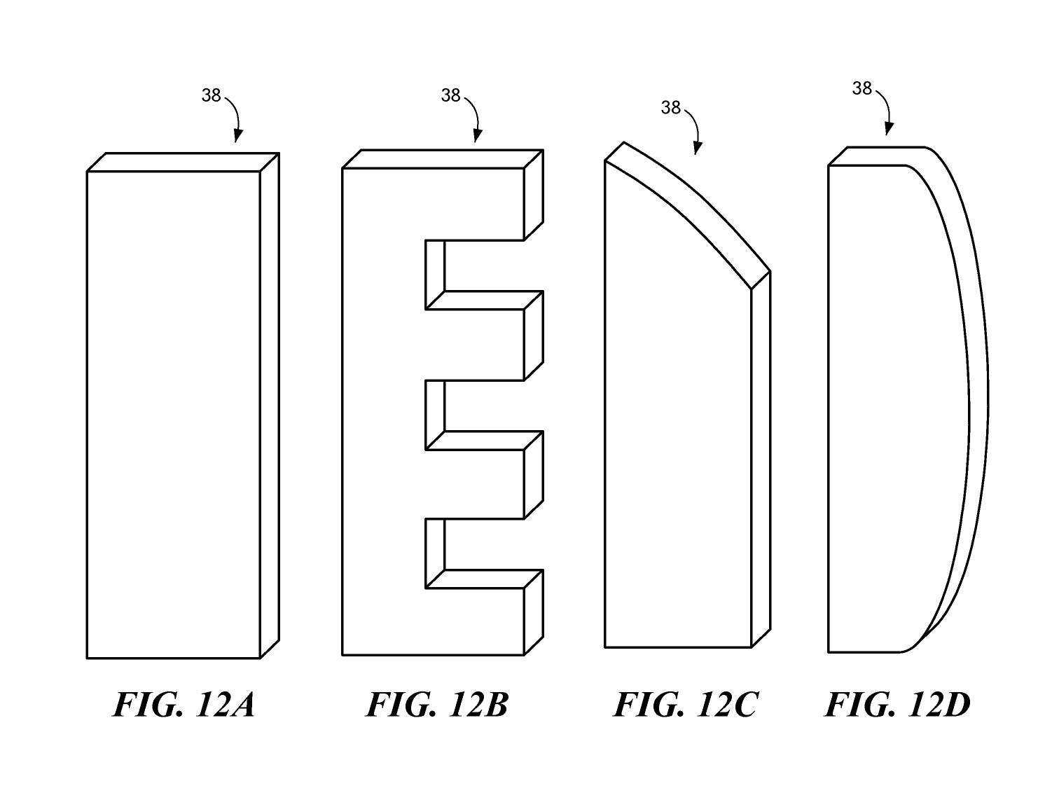

The shape of the ribs 40 also may take on different configurations, depending on the application or intended use. For example, as shown in FIG. 12A, and previously in FIGS. 8A and 11A-11C, one or more of the ribs 40 may be in the form of rectangular strips that each have a substantially uniform width. Alternatively, or in addition, one or more of the ribs 40 may have two or more substantially constant widths, which may be arranged in an alternating pattern, such as that shown in FIG. 12B. Alternatively, or in addition, one or more of the ribs 40 may have varying widths or portions with varying widths. For example, FIG. 12C shows a rib 40 with a continuously varying width at its upper portion and a substantially constant width at its lower portion, and FIG. 12C shows a rib 40 with a continuously varying width.

The ribs 40 may also have different shapes that are either uniform or varying, e.g., oval shapes, irregular shapes, etc. . . . , and/or be positioned adjacent to one another with each rib 40 extending substantially the length of the afterheater 28 in the vertical direction, as shown in FIGS. 10A-10C. Alternatively, the ribs 40 may include shorter sections that are vertically aligned on top of one another with little to no space between sections, or a designated amount of space between sections. The size and shape of the ribs 40 may be varied depending on the desired thickness of the sheet wafers 10 and the degree of temperature control necessary in the afterheater. However, in general, the size and shape should not be too large because the sheet wafer 10 may become too thick at certain areas, and/or have undesirable internal strains or stresses. The size and shape of the ribs 40 thus should be carefully controlled to minimize such strains or stresses, and ensure appropriate sheet wafer thickness.

For example, the two filament holes (or filaments extending therethrough) may be considered as forming a plane extending vertically upwardly through the system 10 along the sheet wafer growth direction. The sheet wafer 10 grows generally parallel to this plane. The ribs 40 may be positioned or aligned along the edge of this plane or the growing sheet wafer 10, or may be positioned anywhere along this vertically extending plane, thus reducing the temperature in that region of the system 10. Reducing the temperature in that region should have the effect of increasing the sheet wafer thickness in the corresponding area.

Accordingly, the afterheater 28 and shield 34 are empirically configured to control the heat profile across a growing/cooling wafer 10 with a principal goal of controlling wafer bow.

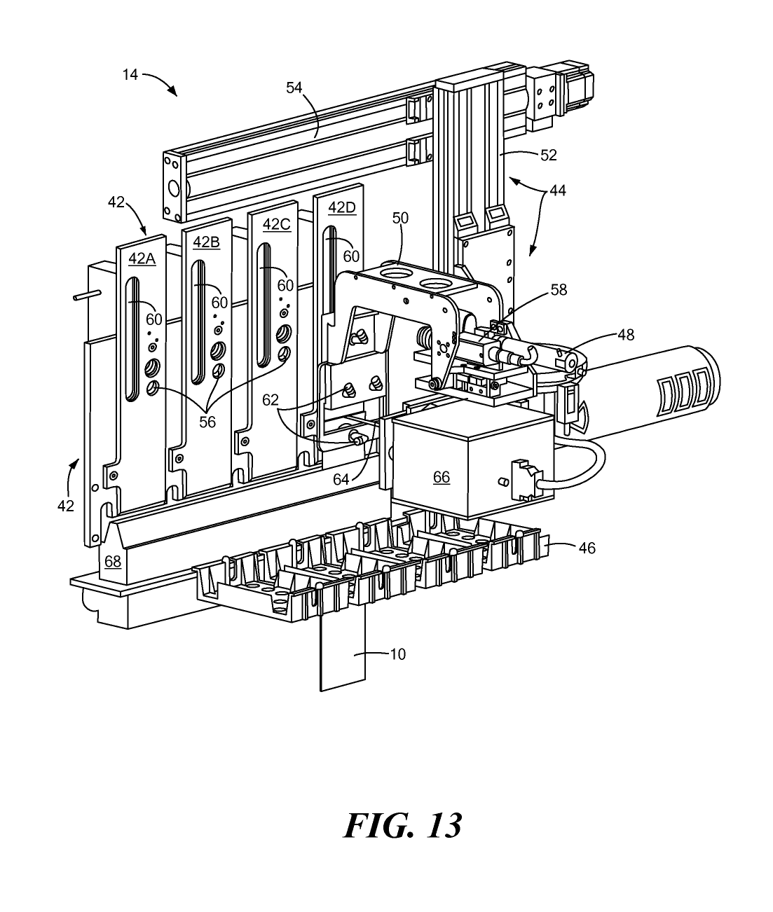

As noted above, wafer growth processes cut the growing wafer to form smaller wafers. This may be a manual process, such as by using an operator or technician to manually cut a score line across the growing wafer. Alternatively, the growing wafer may be cut and removed in an automated process. To that end, FIG. 13 schematically shows additional parts of the furnace that automate this process. These parts are outside of the housing 16 shown in the prior figures (e.g., FIG. 2).

More specifically, FIG. 13 schematically shows a sheet wafer furnace 14 configured in accordance with illustrative embodiments of the invention. This drawing shows the outside of the housing 16 and thus, does not show the afterheater 28, shield 34, crucible 18, and portion of the wafer 10 growing within the housing 16. It nevertheless may include all of the same components as discussed above.

In addition, the furnace 14 has a wafer guide assembly 14 with four guides 42A-42D for guiding four separate filament sheet wafers 10 along four separate growth channels, from the molten silicon. To automate the process, the furnace 14 has a movable robotic assembly 44 for selectively separating (e.g., cutting) sheet wafers 10, and then moving the separated portion (now in a smaller sheet wafer form since it is no longer growing), which forms a smaller wafer 10 and places it into a conventional tray 46. For example, the movable assembly 44 may process a first sheet wafer 10 by 1) separating a portion from the first sheet wafer 10 as it grows, and then 2) placing the separated portion in the tray 46. After placing the separated portion of the first sheet wafer 10 in the tray 46, the movable assembly 44 may repeat the same process with a second growing sheet wafer 10. This process may repeat indefinitely between the four growing sheet wafers 10 until some shut down or stoppage event (e.g., to clean the furnace 14).

To perform this function, the movable assembly 44 has, among other things, a separation mechanism/apparatus (e.g., having a laser assembly 48, discussed immediately below) for separating a portion of the sheet wafer 10, and a rotatable robotic arm 50 for grasping both wafers 10 and growing sheet wafers 10, and positioning the grasped wafers 10 in the tray 46. Consequently, the furnace 14 may substantially continuously produce silicon wafers 10 without interrupting the crystal growth process. Some embodiments, however, can cut the sheet wafers 10 when crystal growth has stopped.

To those ends, the separation apparatus may include a laser assembly 48 that, along with the rest of the movable assembly 44, is vertically movable along a vertical stage 52, and horizontally movable along a horizontal stage 54. Conventional motorized devices, such as stepper motors, control movement of the movable assembly 44. For example, a vertical stepper motor (not shown) vertically moves the movable assembly 44 as a function of the vertical movement of a growing wafer (discussed in greater detail below). A horizontal stepper motor (not shown) moves the assembly 44 horizontally. Of course, as noted, other types of motors may be used and thus, discussion of stepper motors is illustrative and not intended to limit all embodiments.

The flexibility afforded by the vertical and horizontal stages 52 and 54 enables the laser assembly 48 to serially cut multiple growing sheet wafers 10. In illustrative embodiments, the vertical and horizontal stages 52 and 54 are formed primarily from aluminum members that are isolated from the silicon, which can be abrasive. Specifically, exposing the stages 52 and 54 to silicon could impair and degrade their functionality. Accordingly, illustrative embodiments seal and pressurize the stages 52 and 54 to isolate them from the silicon in their environment.

As noted above, the wafer guide assembly 14 has four separate guides 42A-42D (i.e., one for each growth channel) for simultaneously growing four separate sheet wafers 10. When referenced individually or collectively without regard to a specific channel, a guide will be generally identified by reference number 42.

Each guide 42, which is formed primarily from graphite, produces a very light vacuum along its face. This vacuum causes the growing sheet wafer 10 to slide gently along the face of the guide 42 to prevent the sheet wafer 10 from drooping forward. To that end, illustrative embodiments provide a port on the face of each guide 42 for generating a Bernoulli vacuum having a pressure on the order of about 1 inch of water.

Each guide 42 also has a wafer detect sensor 56 for detecting when the growing sheet wafer 10 reaches a certain height/length. As discussed below, the detect sensors 56 each produce a signal that controls processing by, and positioning of, the movable assembly 44. Specifically, after detecting that a given sheet wafer 10 has reached a certain height/length, the detect sensor 56 on a given guide 42 monitoring the given sheet wafer 10 forwards a prescribed signal to logic that controls the movable assembly 44. After receipt, the movable assembly 44 should move horizontally to the given guide 42 to produce a wafer 10. Of course, the movable assembly 44 may be delayed if requests from sensors 56 at other guides 42/channels have not been sufficiently serviced.

Many different types of devices may be used to implement the functionality of the detect sensor 56. For example, a retro-reflective sensor, which transmits an optical signal and measures resultant optical reflections, should provide satisfactory results. As another example, an optical sensor having separate transmit and receive ports also may implement the detect sensor functionality. Other embodiments may implement non-optical sensors.

The movable assembly 44 therefore moves to the appropriate guide 42 in response to detection by the detect sensor 56. In this manner, the movable assembly 44 is capable of serially processing and cutting the four (or more) growing sheet wafers 10. It should be noted that illustrative embodiments apply to other configurations and, as suggested above, to different numbers of guides 42/channels. Discussion of four side-by-side guides 42 thus is for illustrative purposes only.

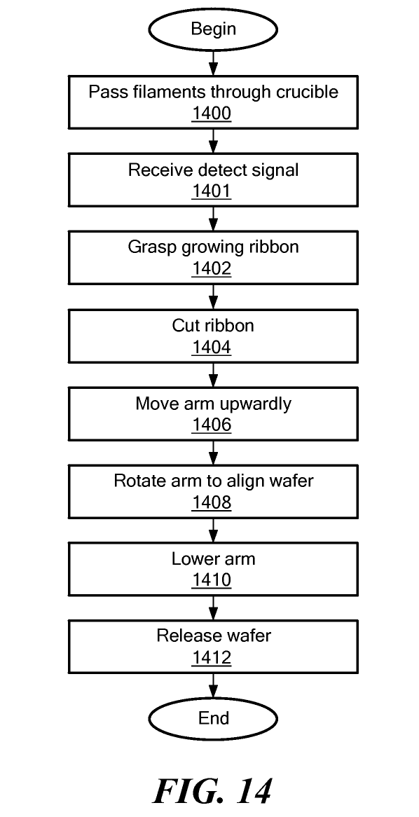

FIG. 14 shows a general process of forming a crystal-based silicon wafer 10 in accordance with illustrative embodiments of the invention. It should be noted that this process shows a few of the many steps of forming a crystal-based silicon wafer 10. Accordingly, discussion of this process should not be considered to include all necessary steps, or in a different order if necessary.

The process begins at step 1400, in which several pairs of filaments 14 are passed through the crucible 18, which contains molten silicon. In illustrative embodiments, the filaments 14 are spaced more than about 145 millimeters apart. For example, the filaments 14 may be spaced about 155 or about 156 millimeters apart. This causes the filament sheet wafers 10 to grow out of the housing 16 and into the afterheater area 28. As discussed above, the afterheater 28 and its shield 34, along with the gas jets 30, control the temperature profile to mitigate bowing.

Next, at step 1401, the detect sensor 56 in one of the channels determines that its locally growing sheet wafer 10 has reached a minimum height. For example, the detect sensor 56 of a given channel may be fixedly positioned approximately six feet above the liquid/solid interface in the crucible. Accordingly, when the growing sheet wafer 10 is approximately 30 centimeters long, the detect sensor 56 forwards the above noted prescribed signal to logic that, sometime after receipt, causes the movable assembly 44 (i.e., the robotic arm 50 and laser assembly 48, among other things) to move into position at the given channel.

After arriving at the relevant channel, the robotic arm 50 grasps the sheet wafer 10 as shown in FIG. 13 (step 1402). To that end, the movable assembly 44 has a conventional vision system for detecting the edge of the growing sheet wafer 10. In illustrative embodiments, the vision system includes a wafer edge detect camera 58, a backlight area 60 for improving contrast for the camera 58, and logic for determining the leading edge of the sheet wafer 10 from a digital image/picture produced by the camera 58. In illustrative embodiments, the backlight area 60 comprises a plurality of light emitting diodes, while the logic includes a software program.

For grasping purposes, the robotic arm 50 has at least three suction areas 62 for securing with a sheet wafer 10 by means of a vacuum (referred to as a “grasping vacuum”). Before applying the grasping vacuum, however, the robotic arm 50 moves so that the three suction areas 62 are positioned very close to the front facing face of the growing sheet wafer 10. For example, the suction areas 62 initially may be positioned about 0.125 inches away from the front face of the growing sheet wafer 10.

As known by those skilled in the art, sheet wafers 10 are extremely fragile. Application of the grasping vacuum at this time thus may cause the sheet wafer 10 to strike the suction areas 62 with a force that can damage the sheet wafer 10. In an effort to reduce the likelihood of this possibility, illustrative embodiments gently urge the sheet wafer 10 toward the suction areas before applying the noted grasping vacuum. Specifically, illustrative embodiments stop applying the Bernoulli vacuum to the back face of the growing sheet wafer 10. Instead, a timed valve on the front face of the guide 42 applies a very light positive pressure to the backside of the sheet wafer 10. This combination of forces should urge the sheet wafer 10 to gently contact or almost contact the suction areas 62 (i.e., closing the small gap), at which time the furnace 14 may begin applying the noted grasping vacuum.

To ensure stability, one of the suction areas 62 is vertically lower than the other two suction areas 62. The suction areas 62 each may include an apparatus (not shown in detail) with a bellows-type suction cup using an external vacuum source. The point of contact between the sheet wafer 10 and the suction cups preferably is relatively soft to minimize contact force between the wafer 10 and suction apparatus.

After grasping one of the sheet wafers 10, the process continues by horizontally cutting the wafer between upper and lower suction areas 62 (step 1404). In illustrative embodiments, a laser (with a scanner 66), such as a fiber laser, generates a laser beam 64 that cuts across the sheet wafer 10 in a predefined manner to produce a sheet wafer 10 having no more than the prescribed amount of bow.

For example, after the camera 58 takes a digital picture of the growing sheet wafer 10, the software may determine which pixels in the digital picture represent the leading edge of the growing sheet wafer 10. Among other ways, the leading edge may take on the appearance of a contrasting row of black pixels in the picture. The software then translates the position of the leading edge within the digital picture to a value representing the physical position of the wafer edge along the guide 42.

This generated value enables the laser to aim its beam at the appropriate location of the growing sheet wafer 10. This position may be a set distance below the leading edge of the wafer 10. For example, this position may be about 15 centimeters below the leading edge and thus, meet certain size specifications without further processing.

Moreover, as known by those skilled in the art, a silicon sheet wafer 10 has portions that are under compression (near the middle of the sheet wafer 10), and other portions that are under tension (near the edges of the sheet wafer 10). These disparate portions generally are in the same horizontal plane. To minimize fracturing while cutting, illustrative embodiments first cut through the portions under compression, and then through the portions under tension. For example, logic associated with the laser assembly 48 may be configured to cut an 82 millimeter wide sheet wafer 10 first through the middle 65 millimeters (the portion generally the portion under compression), and then through the remaining uncut portions (the portions generally the portions under tension). A laser of the laser assembly 48 may cut through the two portions under tension either at the same time (i.e., using the same pass), or serially (using different passes).

To cut through a sheet wafer 10 in that manner, the laser assembly 48 may have a scanner that makes multiple passes across the portion under compression before cutting through portions under tension. In so doing, the laser assembly 48 sequentially cuts through each different type of portion. When using a low power pulse laser, each pass produces a set of holes. The movable laser assembly 48 is programmed, however, to produce holes on each pass that are offset from at least those of the previous pass and other passes. Accordingly, the laser 38 cuts through a silicon sheet wafer 10 having a thickness of about 150-300 microns after a plurality of passes.

For example, the laser of the laser assembly 48 may produce 100 nanosecond pulses at a rate of 20 kilohertz and may move horizontally at a rate of about 2 meters per second. Such a laser may make about 300 passes to cut through the portion of the silicon sheet wafer 10 under compression. To complete the cut through the sheet wafer 10, the laser repeats the multi-pass process for portions under tension. Using a multiple pass process substantially minimizes heat produced by the cutting process, thereby improving results.

Alternative embodiments of the laser cut the wafer 10 straight across the width of the wafer 10 without regard to compression or tension regions. To minimize microcracks and other related problems, however, such embodiments preferably still use a multipass method similar to that discussed above.

In illustrative embodiments, the laser of the laser assembly 48 is a low power, fiber laser that produces a pulsed laser beam 64 (scanning beam 64). For example, the laser 38 may be a RSM PowerLine F fiber laser, distributed by Rofin-Sinar Laser GmbH, of Starnberg, Germany. The PowerLine F fiber laser is a q-switched Yb fiber laser operating at about 1065 nm. After testing, the inventors were surprised to learn that, based on the performance of the noted Rofin laser, low power lasers (i.e., those using the multiple scans as discussed above) produced substantially no microcracks of concern and yet cut quickly enough to work effectively and efficiently in an automated system. For example, the inventors have successfully used low power lasers 38 in four channel systems that grow the sheet wafers 10 at a rate of about 18 millimeters per minute. During testing, a low power laser that takes about 40 seconds to completely cut through a growing sheet wafer 10 moves between the channels to produce silicon wafers 10 efficiently and continuously.

Of course, other brands and types of lasers may be used. For example, alternative embodiments may use higher power lasers, which require only one or two passes. Such lasers, however, undesirably can generate excessive heat and can create microcracks in the resultant wafer 10.

Rather than making a substantially straight cut across a sheet wafer 10, some embodiments cut the sheet wafer 10 in a manner that forms specific edge features (e.g., chamfers). Among other things, the edge features may include rounded corners that further reduce wafer stress.

It should be noted that various embodiments use a number of other laser implementations. For example, a furnace 14 may have a single, stationary laser 38 and a movable fiber optic cable (not shown) that terminates at a movable scanner 66. As another example, each wafer guide 42 may have its own laser, or each wafer guide 42 may have a single laser head that receives energy from a single laser. Rather than use fiber optic cable, some embodiments simply use air as the laser transmission medium. Accordingly, in some embodiments, the laser beam 64 itself may be considered to be part of the movable assembly 44. Moreover, some embodiments may use other techniques for cutting the sheet wafer 10, such as manual saws or scoring devices.

As can be reasonably discerned by FIG. 13, until the grasping vacuum is no longer applied through the suction areas 62, the movable assembly 44 and sheet wafer 10 move at about the same rate and in the same direction—there is substantially no relative movement between the two bodies. By doing this, the growth process continues even while the laser cuts the sheet wafer 10. In addition, unless preconfigured otherwise, the cut across the sheet wafer 10 should be substantially straight. Illustrative embodiments therefore vertically position the suction areas 62 relative to the sheet wafer 10 (e.g., relative to the leading edge of the sheet wafer 10) in a manner that ensures a specific size for the ultimately formed wafer 10 (e.g., 15 centimeters). Among other things, this vertical position thus is a function of the crystal growth rate and the length of time the movable assembly 44 takes to grasp the sheet wafer 10.

Specifically, illustrative embodiments determine the actual growth rate of the sheet wafer 10 many times per second (e.g., 200 times per second). At about the moment that the suction areas 62 apply the grasping vacuum, logic receiving this growth rate information clamps the speed/rate of the movable assembly 44 to a substantially constant rate equal to that growth rate at this time. Of course, at this point, the movable assembly 44 also moves in the same direction as the growing sheet wafer 10.

Cutting in this manner should produce crystal-based filament sheet wafers 10 (also known in the art as “ribbons”) having substantially uniform lengths, with a minimum of microcracks and, preferably, acceptable bow. In alternative embodiments, however, before grasping the growing sheet wafer 10, the movable assembly 44 moves to a fixed location relative to the furnace 14. Such embodiment is unlike the first noted embodiment because it does not position the movable assembly 44 relative to the growing sheet wafer 10. Although such embodiments still move at the above noted determined rate after grasping the sheet wafer 10, they may not necessarily produce substantially uniformly sized wafers 10.

During testing, the inventors noticed that the laser beam 64 began oxidizing portions of the sheet wafer 10 and, consequently, the resultant wafers 10. To minimize this effect, some embodiments add a shielding gas to the region of the furnace 14 cutting the sheet wafer 10. Among other things, the shielding gas may be argon.

After cutting the sheet wafer 10, the robotic arm 50 moves vertically upwardly a very small distance (e.g., 0.125 inches) to ensure complete separation between the removed portion (i.e., the wafer 10) and the remaining sheet wafer 10 (step 1406). If the separation is not complete, the method may cause the laser 38 again to cut across to the sheet wafer 10 in the unseparated area, or across the entire width of the sheet wafer 10 (in the same area that previously was cut).

Next, the movable assembly 44 moves upwardly a greater distance to provide enough clearance for rotating the arm 50. At some point before this time, the grasping vacuum applied to the remaining portion of the sheet wafer 10 should be released. The grasping vacuum applied to the newly cut wafer 10, however, should continue to be applied.

In addition, to provide further clearance, the robotic arm 50 may move in a direction generally normal to the face of the sheet wafer 10. For example, the robotic arm 50 may move about 20 millimeters away from the face of the sheet wafer 10.

After providing the appropriate clearance, the process then continues to step 1408, which rotates the arm 50 about ninety degrees to align the wafer 10 with the underlying tray 46. The stepper motor then lowers the robotic arm 50 (step 1410) to a cavity in the tray 46. At this point, the grasping vacuum may be released, thus permitting the wafer 10 to fall gently onto the tray 46 (step 1412). To minimize the impact of the fall, the wafer 10 should be very close to the tray 46 before it is released. In addition, the tray 46 can have features to minimize impact (e.g., soft portions or specialized geometry).

For safety reasons, the entire movable assembly 44 preferably is enclosed within the above noted housing 16 (FIG. 2 and others) formed of an opaque material, such as steel. The housing 16 is not shown in FIG. 13 to permit a fuller view of the movable assembly 44. The growing sheet wafers 10 therefore extend upwardly, from the crucible, through a rubber light seal 68 and into the housing 16. It should be reiterated that the drawings are schematic and thus, are not drawn to scale.

As noted above, each resultant filament sheet wafer 10 includes both filaments 12. In alternative embodiments, however, the process removes one or both filament sheet wafers 10. Specifically, the process may remove an edge of a growing sheet wafer 10, or an edge of a sheet wafer 10 cut from the growing sheet wafer 10. Either way, the filament 12 may be removed, or, as yet another option, the filament 12 may remain. Among other benefits, this step may both generally planarize the crystal/wafer edge and remove at least a portion of the smaller grains that act as electron traps. Accordingly, the resultant wafers 10: 1) have improved electrical properties, 2) may be positioned in closer proximity to neighboring wafers 10, and 3) maximize the area of a back-surface contact (not shown). In addition, removal of the smaller grains should improve the aesthetic appearance to some observers.

As filament sheet wafers 10, they have very smooth top and bottom surfaces. For example, the top surface and/or the bottom surface of the filament sheet wafer 10 may have a surface roughness RMS value of between about 0.005 microns and about 0.04 microns. This is unlike other types of wafers, such as CZ wafers, which, before being subjected to any smoothing operations, have relatively high surface roughness due to their required sawing operations.

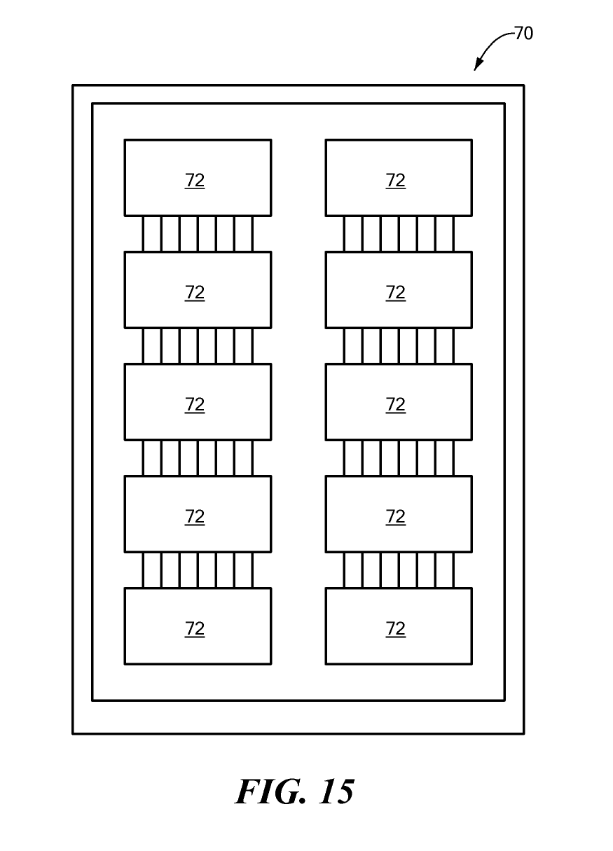

The filament wafer 10 may be incorporated into a number of devices, such as a solar cell and solar panel. For example, FIG. 15 schematically shows a photovoltaic module 70 (also known as a photovoltaic panel 70 or solar panel 70) that may incorporate solar cells 72 having filament sheet wafers 10 configured in accordance with illustrative embodiments of the invention. Among other things, the photovoltaic module 70 has a plurality of electrically and physically interconnected photovoltaic cells 72 within a rigid frame. The module 70 also may have an encapsulating layer (not shown) and glass top layer (not shown) to protect the cells, and a backskin (not shown) to further protect the cells and provide a back support.

It should be reiterated that the module 70 shown in FIG. 15 serves merely as a schematic drawing of an actual module. Accordingly, the number of cells 72 and, of course, the cell topology can vary significantly within the context of the below description.

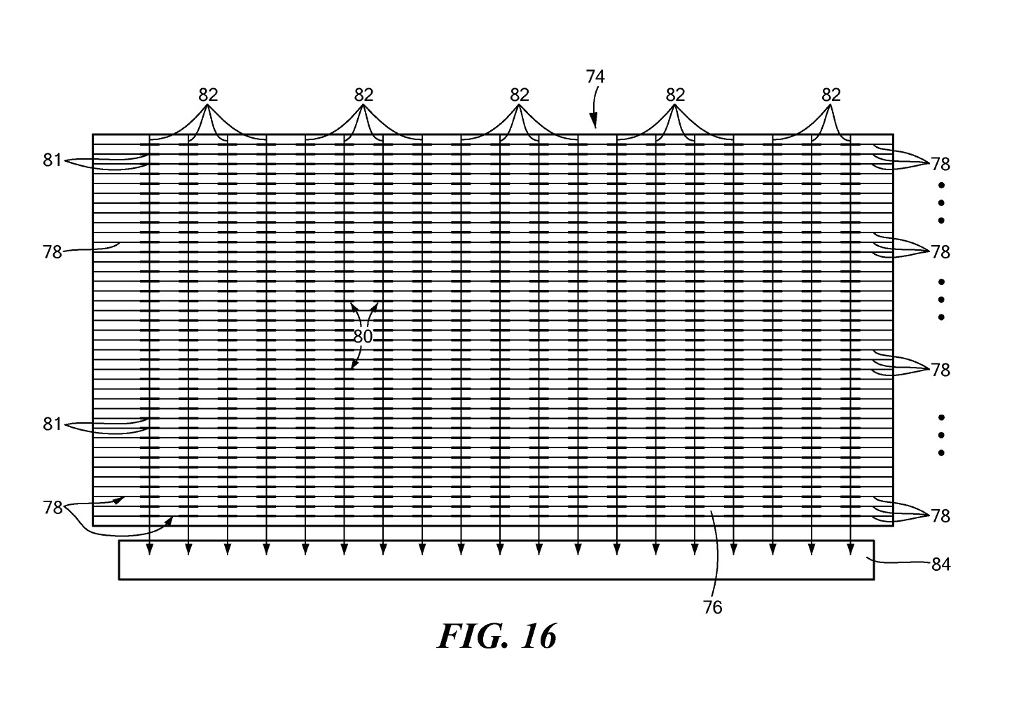

FIG. 16 schematically shows a top view of a photovoltaic cell 72 incorporating filament sheet wafers 10 configured in accordance with illustrative embodiments of the invention. As shown, the top surface 74 has an antireflective coating 76 to capture more light incident light, and a pattern of deposited/integral conductive material to capture electric current.

Specifically, the conductive material includes a plurality of thin fingers 78 traversing generally lengthwise (horizontally from the perspective of the figure) along the wafer 10 (also referred to as “substrate 10”), and a plurality of discontinuous busbars 80 traversing a generally along the width (vertically from the perspective of the figure) of the substrate 10. As shown and discussed below, each of the busbars 80 has regularly spaced discontinuities along its length. In the example shown, the busbars 80 are generally arranged as a pattern of pads 81. This pattern is more or less perpendicular to the fingers 78. Some embodiments, however, have solid busbars 80.

Some embodiments may form the busbars 80 and fingers 78 in different orientations. For example, the fingers 78, busbars 80, or both could traverse in a random manner across the top face 74 of the substrate 10, at an angle to the fingers 78 and busbars 80 shown, or in some other pattern as required by the application.

The photovoltaic cell 72 also has a plurality of tab conductors 82 (referred to generally as “tabs 82”) electrically and physically connected to the busbars 80. For example, the tabs 82 may be formed from silver, silver plated copper wires, or silver plated copper wires to enhance conductivity. The tabs 82 transmit electrons gathered by the fingers 78 to a metallic strip 84, which is connectible to either an external load or another photovoltaic cell (e.g., as shown in FIG. 1).

Illumination of the top face 74 of the substrate 10 generates carriers; namely, holes and electrons. The bottom face (not shown) of the substrate 10 does not receive light and thus, may be completely covered to maximize its efficiency in collecting charge carriers. The photovoltaic cell 72 also has a metallic strip 84 connected with the tabs 82. Thus, the cell 72 serially connects with other photovoltaic cells in a panel by connecting its metallic strip 84 to a corresponding metal contact on the neighboring cell's 72 bottom side (not shown).

Accordingly, illustrative embodiments form commercial grade, wide sheet wafers 10. For example, illustrative embodiments form commercial grade filament sheet wafers 10 having widths of between about 150 millimeters and about 160 millimeters.

Although the above discussion discloses various exemplary embodiments of the invention, it should be apparent that those skilled in the art can make various modifications that will achieve some of the advantages of the invention without departing from the true scope of the invention.

What is claimed is:

1. A sheet wafer comprising:
a generally flat, generally rectangular shaped body having a length and a width, the width being between about 145 mm and 165 mm;
a first filament extending generally perpendicular to the width of the body; and
a second filament spaced from the first filament and extending generally perpendicular to the width of the body,
the first and second filaments at least partially encapsulated by a wafer material,
the wafer material and the filaments forming at least a portion of the body.

2. The sheet wafer is defined by claim 1 wherein the width is between about 155 mm and 157 mm.

3. The sheet wafer is defined by claim 2 wherein the width is about 156 mm.

4. The sheet wafer is defined by claim 1 wherein the wafer material comprises multi-crystalline silicon.

5. The sheet wafer is defined by claim 1 wherein the wafer material comprises single crystal silicon.

6. The sheet wafer is defined by claim 1 wherein the wafer comprises a filament sheet wafer.

7. The sheet wafer is defined by claim 1 wherein the wafer comprises wafer material having a plurality of grains with a minimum dimension of about 2 centimeters.

8. The sheet wafer is defined by claim 1 wherein the wafer has an irregular thickness between the filaments, the wafer having an average thickness that is between about 80 and 170 microns.

9. The sheet wafer as defined by claim 1 wherein the width is defined by two sides that are generally parallel with the first and second filaments, each side being defined at least in part by the wafer material.

10. The sheet wafer as defined by claim 1 wherein the generally flat body has a bow of no greater than about 2.5 millimeters.

11. The sheet wafer as defined by claim 10 wherein the generally flat body has a bow of less than about 2 millimeters.

12. The sheet wafer as defined by claim 1 wherein the body has a top face with a surface roughness RMS value of between about 0.005 microns and about 0.04 microns.

13. A sheet wafer comprising:
a generally rectangular body having a length and a width, the length being defined by an upper length side and a lower length side, the width being defined by a left width side and a right width side;
a first filament within the body and generally parallel with the left width side;
a second filament within the body and generally parallel with the right width side,
wafer material encapsulating at least a portion of the first filament and the second filament to at least in part form the generally flat body, the generally flat body having a bow of no greater than about 2.5 millimeters,
the width being between about between about 145 mm and 165 mm.

14. The sheet wafer as defined by claim 13 wherein at least one of the first filament and the second filament are exposed at least at one of the upper length side and the lower length side.

15. The sheet wafer as defined by claim 13 wherein the generally flat body has a bow of less than about 2 millimeters.

16. The sheet wafer is defined by claim 13 wherein the width is between about 155 mm and 157 mm.

17. The sheet wafer is defined by claim 16 wherein the width is about 156 mM.

18. The sheet wafer is defined by claim 13 wherein the wafer material comprises multi-crystalline silicon.

19. The sheet wafer is defined by claim 13 wherein the wafer material comprises single crystal silicon.

20. The sheet wafer is defined by claim 13 wherein the wafer material has a plurality of grains with a minimum dimension of about 2 centimeters.

21. The sheet wafer is defined by claim 13 wherein the wafer has an irregular cross-sectional thickness between left width side and the right width side, the wafer having an average thickness that is between about 80 and 170 microns.

22. A method of forming a sheet wafer, the method comprising:
passing a pair of filaments through a crucible of molten material, the crucible being within a wafer furnace, the pair of filaments being spaced greater than about 145 mm apart to form a growing sheet wafer;
controlling the cooling profile within the wafer furnace; and
removing a portion of the growing sheet wafer to form a grown sheet wafer, the grown sheet wafer having a width of between about 146 mm and 165 mm and having a body formed from the molten material and the pair of filaments, the molten material at least in part encapsulating the pair of filaments.

23. The method as defined by claim 22 wherein controlling comprises securing a shield within the wafer furnace to at least in part cause the rate of temperature change across the width of the grown sheet wafer to be generally constant.

24. The method as defined by claim 22 wherein controlling causes the grown sheet wafer to have a bow of no greater than about 2.5 mm.

25. The method as defined by claim 22 wherein the molten material becomes single crystal silicon or multi-crystalline silicon when solid.

26. The method as defined by claim 22 wherein the pair of filaments are spaced between about 155 mm and 157 mm apart.

27. The sheet wafer formed by the method defined by claim 22.

28. The method as defined by claim 22 further comprising removing at least a portion of at least one of the filaments from the grown sheet wafer, the width of the body being between 145 mm and 165 mm after the at least one filament is removed.

29. The method as defined by claim 22 wherein controlling comprises directing a gas from a gas jet toward a local region of the growing sheet wafer.
